(19) United States
(12) Patent Application Publication
(10) Pub. No.: US 2014/0316103 A1
(43) Pub. Date: Oct. 23, 2014

(54) INSULATING MATERIAL USING EPOXY RESIN COMPOSITION

(71) Applicant: AIR WATER INC., Sapporo-shi, Hokkaido (JP)

(72) Inventor: Kou Takahashi, Kasima-shi (JP)

(21) Appl. No.: 14/360,832

(22) PCT Filed: Nov. 22, 2012
(86) PCT No.: PCT/JP2012/081008

§ 371 Date: May 27, 2014

(30) Foreign Application Priority Data
Nov. 29, 2011 (JP) 2011-259741

(51) Int. Cl. H05K 1/03; C08G 59/40

(52) U.S. Cl. CPC H05K 1/0353; C08G 59/4085
USPC 528/421

(57) ABSTRACT

An insulating material obtained by using an epoxy resin composition comprising, as an epoxy resin curing agent, a polycondensation-type aryloxysilane compound contained in an amount of 50 to 100 wt %, having a hydroxyl group equivalent in a range of 1,000 to 8,000 g/eq, and an epoxy resin having an epoxy equivalent of 200 to 500, wherein a thermally cured product obtained by curing this epoxy resin composition at a temperature of 180° C. or lower, shows a dielectric constant and a dielectric loss tangent of 3.00 or smaller and 0.015 or smaller, respectively, at 1 GHz under normal temperature. The insulating material using the epoxy resin composition can exhibit both excellent dielectric properties and practical characteristics, and is suitable for an interlayer insulating material of a multilayer printed circuit board.

### TECHNICAL FIELD

The present invention relates to an insulating material using an epoxy resin composition. In more detail, the present invention relates to an insulating material suitable for formation of an insulating layer of a multilayer printed circuit board using the epoxy resin composition.

### BACKGROUND ART

In response to enhancement of performance such as high functionalization, densification of information and communication equipments in recent years, performance adapting thereto has been required also to a printed circuit board. In particular, because of use of a high frequency signal for increased volume and high speed of information transmission quantity, and to suppress transmission loss caused thereby, there has been required a material having both low dielectric constant and low dielectric loss tangent, as an insulating layer of a multilayer printed circuit board. In particular, an epoxy-based material has been used widely in said application in view of high adhesive property or price thereof, and various approaches have been challenged up to now toward improvement of dielectric properties thereof.

In general, a hydroxyl group present in an epoxy resin cured product is a cause to increase dielectric constant, and to attain low dielectric constant, there have been challenged up to now approaches such as using a phenol-based curing agent having high hydroxyl group equivalent, or using an active ester-type curing agent having an acyl-protected structure of polyvalent phenols. However, even in these approaches, it is a present situation that there has still not been found a good method to overcome both of a problem on dielectric properties and a problem on practical use, such that realization of low dielectric constant and low dielectric loss tangent, to required levels of said applications in recent years, is difficult; or severe curing condition is required due to low reactivity of a curing agent, which generates practical restriction; or the like.

On the other hand, a phenoxysilane compound is also possible to utilize as the epoxy resin curing agent. This is the same hydroxyl group protection-type curing agent as an active ester, however, because the active ester has low reactivity and thus requires higher curing temperature as compared with a phenol-based curing agent, while the phenoxysilane compound is possible to prepare a cured product at the same curing temperature as that for a conventional phenol-based curing agent (PATENT DOCUMENTS 1 to 4).

### CITATION LIST

PATENT DOCUMENT 1: JP-A-7-53675

PATENT DOCUMENT 2: JP-A-8-208807

PATENT DOCUMENT 3: JP-A-10-168283

PATENT DOCUMENT 4: JP-A-2005-145911

### SUMMARY OF INVENTION

### Technical Problem

In view of the above problems, the present invention provides an insulating material using an epoxy resin composition having both excellent dielectric properties and practical characteristics.

The present invention relates to an insulating material suitable for an interlayer insulating material of a multilayer printed circuit board using the epoxy resin composition having both excellent dielectric properties and practical characteristics.

### Solution to Problem

The present invention provides an insulating material obtained by using an epoxy resin composition comprising, as an epoxy resin curing agent, a polycondensation-type aryloxysilane compound contained in an amount of 50 to 100 wt %, having a skeleton shown by the following general formula (1) and having a hydroxyl group equivalent in a range of 1,000 to 8,000 g/eq, and an epoxy resin having an epoxy equivalent of 200 to 500, wherein a thermally cured product obtained by curing this epoxy resin composition at a temperature of 180° C. or lower, shows a dielectric constant and a dielectric loss tangent of 3.00 or smaller and 0.015 or smaller, respectively, at 1 GHz under normal temperature:

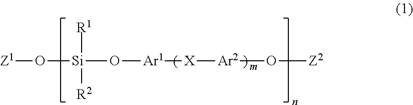

(wherein R¹ and R² represent hydrocarbon groups having carbon atoms of 1 to 12; Ar¹ and Ar² represent arylene groups having carbon atoms of 6 to 10, wherein a substitution group may be present; X represents a direct bonding, a divalent hydrocarbon group having carbon atoms of 1 to 6, O, S or SO₂; m represents an integer of 0 to 2; n represents an integer of 1 to 20; Z¹ represents a group shown by the following general formula (2); and Z² represents hydrogen or a group shown by the following general formula (3))

HO—AR¹X—Ar²ₘ (2)

(wherein Ar¹, Ar² and X are the same as in formula (1))

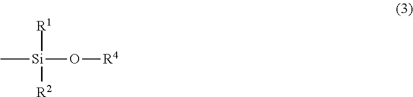

(wherein R¹ and R² are the same as in formula (1), and R⁴ represents an alkyl group having carbon atoms of 1 to 4).

The present invention also provides an insulating material obtained by using an epoxy resin cured product, wherein a thermally cured product obtained by thermal curing of the aforesaid epoxy resin composition shows a dielectric constant of 3.00 or smaller and a dielectric loss tangent of 0.015 or smaller, at 1 GHz under normal temperature

An aspect where said insulating material is an interlayer insulating material of a multilayer printed circuit board is a preferable aspect of the present invention.

The present invention further provides a multilayer printed circuit board prepared by using the aforesaid interlayer insulating material.

### Advantageous Effects of Invention

According to the present invention, there is provided an insulating material suitable for an interlayer insulating material using an epoxy resin composition having both excellent dielectric properties and practical characteristics.

Use of a specific epoxy resin composition of the present invention enables to provide an insulating material of a multilayer printed circuit board having both excellent dielectric properties and practical characteristics.

That is, the epoxy resin composition containing a polycondensation-type aryloxysilane compound, as an epoxy curing agent, provides smooth progression of thermal curing at curing temperature in using a conventional phenol-based curing agent, and provides an interlayer insulation layer having low dielectric constant and low dielectric loss tangent.

### DESCRIPTION OF EMBODIMENTS

The present invention provides an insulating material obtained by using an epoxy resin composition comprising, as an epoxy resin curing agent, a polycondensation-type aryloxysilane compound contained in an amount of 50 to 100 wt %, having a skeleton shown by said general formula (1) and having a hydroxyl group equivalent in a range of 1,000 to 8,000 g/eq, and an epoxy resin having an epoxy equivalent of 200 to 500, wherein a thermally cured product obtained by curing this epoxy resin composition at a temperature of 180° C. or lower, shows a dielectric constant and a dielectric loss tangent of 3.00 or smaller and 0.015 or smaller, respectively, at 1 GHz under normal temperature.

The epoxy resin curing agent to be used in the present invention is the one that contains a polycondensation-type aryloxysilane compound having a skeleton shown by said general formula (1), in a proportion of 50 to 100 wt %, wherein R¹ and R² are each the same or different hydrocarbons, which may contain a foreign atom, for example, a fluorine atom or an oxygen atom, and which can include, for example, a substituted or an unsubstituted alkyl group such as methyl, ethyl, isopropyl, n-propyl, isobutyl, n-butyl, sec-butyl, tert-butyl, 2-ethylhexyl, cyclohexyl, benzyl, trifluoromethyl, 2-ethoxyethyl and vinyl group; a substituted or unsubstituted aryl group such as phenyl, 2-, 3- or 4-methylphenyl, 2-, 3- or 4-methylphenyl, 2-, 3- or 4-ethylphenyl, 2-, 3- or 4-isopropylphenyl, 2-, 3- or 4-isobutylphenyl, 2-, 3- or 4-tert-butylphenyl, 2-, 3- or 4-fluorophenyl, 2-, 3- or 4-ethoxyethylphenyl, 2-, 3- or 4-phenylphenyl and α- or β-naphthyl group. By changing the kind of R¹ and R², cure rate or dielectric properties of the cured product can be adjusted, however, in consideration of easy availability of raw materials, it is preferable that R¹ and R² are a methyl group or a phenyl group.

The polycondensation-type aryloxysilane compound can be synthesized by a reaction of polyvalent phenols to be described later with dialkoxysilanes represented by the following general formula (4) (refer to JP-A-2005-145911). Alcohols derived from R³ and R⁴ are by-produced by the reaction, and, in view of synthesis, as R³ and R⁴, those having carbon atoms of 1 to 4 are selected, which provide easy removal of the obtained alcohols, and as the group, there is included a lower alkyl group such as methyl, ethyl, isopropyl, n-propyl, isobutyl, n-butyl and sec-butyl group. Specifically, there is exemplified diethoxydimethylsilane, dipropoxydimethylsilane, dibutoxydimethylsilane, dimethoxymethylphenylsilane, dimethoxydiphenylsilane, or the like. It should be noted that in silylation of the polyvalent phenols by dialkoxysilanes, it is preferable to perform silylation in a raw material ratio to attain 0.5 to 1.5 equivalent, in particular, 0.7 to 1.0 equivalent of the alkoxysilyl group of dialkoxysilanes, relative to 1 equivalent of the hydroxyl group of the polyvalent phenols, in view of characteristics.

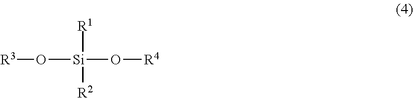

(wherein R¹ and R² are the same as in formula (1), and R³ and R⁴ represent alkyl groups having carbon atoms of 1 to 4).

In said general formula (1), Ar¹ and Ar² are arylene groups such as a phenylene group and a naphthylene group, which may have a substituent such as a hydrocarbon group, halogen and a hydroxyl group, in the aromatic ring; in addition, X is direct bonding, a divalent hydrocarbon group, such as, for example, methylene, ethylene, ethylidene, isopropylidene, butylidene, cycloalkylene, 0, S or SO₂; m is an integer of 0 to 2, preferably, 0 or 1. More specifically, as the group represented by the following (5) in the general formula (1),

O—Ar¹X—Ar²ₘO— (5)

there can be exemplified a residual group of polyvalent phenols such as hydroquinone, resorcin, catechol, methylhydroquinone, ethylresorcin, propylcatecol, pyrogallol, phloroglucin, 1,2,4-trihydroxybenzene, o,o′-biphenol, o,m′-biphenol, o,p′-biphenol, m,m′-biphenol, m,p′-biphenol, p,p′-biphenol, bisphenol-F, bisphenol-A, bisphenol-S, 1,2-dihydroxynaphthalene, 1,3-dihydroxynaphthalene, 1,4-dihydroxynaphthalene, 1,5-dihydroxynaphthalene, 1,6-dihydroxynaphthalene, 1,7-dihydroxynaphthalene, 1,8-dihydroxynaphthalene, 2,3-dihydroxynaphthalene, 2,6-dihydroxynaphthalene, 2,7-dihydroxynaphthalene, a phenol novolac resin, a cresol novolac resin, a phenol aralkyl resin, a naphthol aralkyl resin, a triphenol methane-type novolac resin, a dicyclopentadiene modified phenol resin and the like. Among these, it is preferable to be a residual group of bivalent phenols.

The polycondensation-type aryloxysilane compound is obtained as a mixture each having a different n value in the general formula (1), generally based on a preparation method thereof. Too large average value of n causes decrease in solubility in making varnish, while on the contrary, too small value makes difficult to obtain good dielectric properties, as well as, in the case where many components corresponding to the general formula (3) in Z² of the general formula (1) are present, the voids tends to be generated in the thermally cured product. Accordingly, suitable average value of n may be enough as long as it is within a range of 1 to 20, and it is desirable to set within a range of 12 to 18, although it depends on the kind of raw materials used or mixing ratio with other kind of a curing agent.

As the epoxy resin curing agent to be used in the present invention, the polycondensation-type aryloxysilane compound may be used alone, and it also may be used in combination with other kind of epoxy resin curing agents. Specifically, it is preferable to use the polycondensation-type aryloxysilane compound in combination with a phenol-based curing agent which includes polyvalent phenols having two or more valents such as a phenol novolac resin, a cresol novolac resin, a phenol aralkyl resin, a naphthol aralkyl resin, a triphenol methane-type novolac resin and a dicyclopentadiene modified phenol resin; and also includes hydroxyl group protected-type phenol-based curing agent such as active esters obtained by acyl-protecting the hydroxyl group of the polyvalent phenols, and plural kinds of the other kind of epoxy resin curing agents may be used in combination. Among these, use of polyvalent phenols having a hydroxyl group equivalent of 200 g/eq or more, or a hydroxyl group protected-type phenol-based curing agent such as active esters, is particularly preferable. It is preferable that proportion of the polycondensation-type aryloxysilane compound is set at 50 to 100% by weight, in total amount of the epoxy resin curing agents including the other kind of epoxy resin curing agents, in consideration of obtaining good dielectric properties.

As the epoxy resin to be used in the present invention, a known one can be used. For example, there is included an epoxy resin having divalent or more epoxy group such as a glicidyl ether-type epoxy resin such as a bisphenol A-type epoxy resin, a bisphenol F-type epoxy resin, a phenol novolac-type epoxy resin, a cresol novolac-type epoxy resin, a biphenyl-type epoxy resin, a phenol biphenyl aralkyl-type epoxy resin, an epoxy compound of an aralkyl resin by xylilene bonding such as phenol and naphthol, an epoxy compound of a dicyclopentadiene modified phenol resin, a dihydroxynaphthalene-type epoxy resin and a triphenol-methane type epoxy resin; glycidyl ester-type epoxy resin; and a glycidyl amine-type epoxy resin. These epoxy resins may be used alone or two or more kinds may be used in combination. In particular, in view of obtaining good dielectric properties, it is preferable to use the phenol biphenyl aralkyl-type epoxy resin; epoxy compound of the aralkyl resin by xylilene bonding such as phenol and naphthol; and the ones having high epoxy equivalent such as the epoxy compound of the dicyclopentadiene modified phenol resin.

In curing the epoxy resin, combined use with a curing accelerator is preferable. As such a curing accelerator, a known curing accelerator for curing an epoxy resin by a phenol-based curing agent can be used, there is included, for example, a tertially amine compound, a quaternary ammonium salt, imidazoles, a phosphine compound and a phosphonium salt. More specifically, there can be included a tertially amine compound such as triethylamine, triethylenediamine, benzyldimethylamine, 2,4,6-tris(dimethylaminomethyl) phenol and 1,8-diazabicyclo[5.4.0]undecene-7; imidazoles such as 2-methylimidazole, 2,4-dimethylimidazole, 2-ethyl-4-methylimidazole, 2-phenylimidazole and 2-phenyl-4-methylimidazole; a phosphine compound such as triphenylphosphine, tributylphosphine, tri(p-methylphenyl)phosphine, tri(nonylphenyl)phosphine and the like; a phosphonium salt such as tetraphenylphosphonium tetraphenylborate and tetraphenylphosphonium tetranaphthoic acid borate; and a betaine-like organic phosphorus compound such as triphenyl phosphonio phenolate and a reaction product between benzoquinone and triphenylphosphine. In particular, in view of performing smooth curing by the polycondensation-type aryloxysilane compound, use of a tertially amine compound, imidazoles, a phosphonium salt or a betaine-type organic phosphorus compound is preferable.

As blending ratio of the epoxy resin curing agent and the epoxy resin of the present invention, it is preferable that equivalent ratio of a reactive functional group of the epoxy resin curing agent/an epoxy group of the epoxy resin is in a range of 0.5 to 1.5, and in particular, 0.8 to 1.2. It is preferable that the curing accelerator is used in a range of 0.1 to 5 parts by weight relative to 100 parts by weight of the epoxy resin.

In the epoxy resin composition of the present invention, curing can be progressed at the temperature that curing of the blending using a known phenol-based curing agent is performed, for example, in a temperature range of 100 to 250° C., although it depends on blending components and composition ratio thereof. Further, it is also possible in the epoxy resin composition of present invention to prepare a cured product at 180° C. or lower, although at the temperature sufficient curing is difficult for a blending using the known active esters to be used aiming at obtaining good dielectric properties.

In the epoxy resin compound of the present invention, a solvent, an inorganic filler, a coloring agent, a thickener, a silane coupling agent, a flame retardant, a low stress agent or the like may be added or used by reacting them in advance, as needed.

The epoxy resin composition of the present invention is suitable for, in particular, an interlayer insulating material of a multilayer printed circuit board. For example, varnish for interlayer insulation to form an insulating layer can be obtained by dissolving the epoxy resin composition of the present invention in a solvent and coating it onto a circuit board; by impregnating the varnish-like epoxy resin composition to glass fiber and performing heating treatment, prepreg of said application can be prepared; and by heat treating the varnish-like epoxy resin composition on a supporting film to make a film-like substance, an adhesive sheet of said application can be prepared. Even these are used in any form, an interlayer insulating material of a multilayer printed circuit board can be prepared.

### EXAMPLES

Explanation will be given below more specifically on the present invention with reference to Examples and Comparative Example, however, the present invention should not be limited to these Examples.

### Reference Example 1

Into a flask with a volume of 500 ml, 110.11 g (1.00 mole) of resorcin, 175.00 g (0.96 mole) of dimethoxymethylphenylsilane, and 0.28 g (1.0 millimole) of tetraisopropoxytitanium are charged and melted at 160° C. and stirred for 20 hours. The obtained polycondensation-type aryloxysilane compound was 223.87 g, and this was referred to as a curing agent A. Hydroxyl group equivalent calculated from weight change before and after the reaction, is 2795 g/eq, and reactive functional group equivalent relative to the epoxy group is 112 g/eq.

### Reference Example 2

Into a flask with a volume of 500 ml, 124.14 g (1.00 mole) of methylhydroquinone, 175.00 g (0.96 mole) of dimethoxymethylphenylsilane and 0.28 g (1.0 millimole) of tetraisopropoxytitanium were charged and melted at 160° C. and stirred for 20 hours. The obtained polycondensation-type aryloxysilane compound was 224.15 g, and this was referred to as a curing agent B. Hydroxyl group equivalent calculated from weight change before and after the reaction, is 2970 g/eq, and reactive functional group equivalent relative to the epoxy group is 119 g/eq.

### Reference Example 3

A phenol biphenyl aralkyl resin represented by the following general formula (6) (HE200C-10, produced by Air water Co., Ltd.) was referred to as a curing agent C.

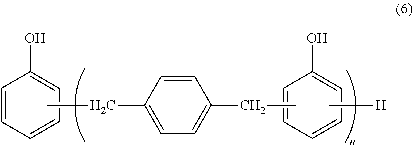

(wherein n represents a number of 1 to 10).

### Example 1

An epoxy resin represented by the following general formula (7) (NC-3000P, produced by Nippon Kayaku Co., Ltd., a biphenyl aralkyl-type having an epoxy equivalent of 272 g/eq), the curing agent A obtained in Reference Example 1, and 1,8-diazabicyclo[5.4.0]undecene-7 were blended in a ratio shown in Table 1, and after they were sufficiently mixed, they were kneaded on two rolls at 85° C.±3° C., cooled and crushed to obtain a composition for molding. After this composition for molding was molded using a transfer molding machine, under a pressure of 100 kgf/cm², at 175° C. for 2 minutes, two kinds of test pieces for property evaluation were prepared by post cure at 180° C. for 6 hours, and post cure at 200° C. for 6 hours. Properties of the obtained test pieces were measured and results thereof are shown in Table 1.

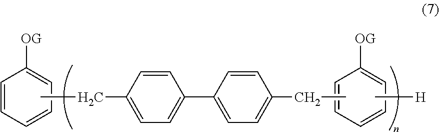

(wherein G represents a glycidyl group, and n represents a number of 1 to 10).

### Example 2

A composition for molding was prepared similarly as in Example 1, except by using the curing agent B described in Reference Example 2, instead of the curing agent A obtained in Reference Example 1, from which composition test pieces for property evaluation were prepared. Properties of the obtained test pieces were measured and results thereof are shown in Table 1.

### Comparative Example

A composition for molding was prepared similarly as in Example 1, except by using the curing agent C described in Reference Example 3, instead of the curing agent A obtained in Reference Example 1, from which composition test pieces for property evaluation were prepared. Properties of the obtained test pieces were measured and results thereof are shown in Table 1.

Measurement of properties in the present invention was performed by the following methods.

### (1) Glass Transition Temperature

Coefficient of linear expansion of the test piece was measured by TMA at a temperature rising rate of 10° C./minute, and an inflection point of the coefficient of linear expansion was adopted as glass transition temperature.

### (2) Dielectric Constant and Dielectric Loss Tangent

Dielectric constant and dielectric loss tangent at 1 GHz were measured in accordance with JIS C6481 (measurement error range: 3% or less for dielectric constant, and 5% or less for dielectric loss tangent).

TABLE 1

| | | | | | Comp. |
|---|---|---|---|---|---|
| | | | Example 1 | Example 2 | Example |
| Blending Agents | Curing agent | Curing agent A | 0.29 | | |
| <parts by weight> | | Curing agent B | | 0.30 | |
| | | Curing agent C | | | 0.43 |
| | Epoxy resin | Biphenyl aralkyl-type | 0.70 | 0.69 | 0.56 |
| | Curing | DBU | 0.01 | 0.01 | 0.01 |
| | accelerator | | | | |
| Mechanical | Tg [° C.] | Post cure at 180° C. | 122 | 119 | 123 |
| properties | | Post cure at 200° C. | 123 | 120 | 124 |
| Dielectric | Dielectric | Post cure at 180° C. | 2.98 | 2.97 | 3.12 |
| properties | constant | Post cure at 200° C. | 2.97 | 2.95 | 3.12 |
| | Dielectric | Post cure at 180° C. | 0.011 | 0.013 | 0.020 |
| | loss tangent | Post cure at 200° C. | 0.011 | 0.012 | 0.019 |

From Table 1, it is understood that glass transition temperature observed in all test pieces has little difference on measurement results of the cured product at 180° C. and the cured product at 200° C., and thermal curing was progressed without any problem, even at a lower temperature of 180° C. or lower. In addition, Examples 1 and 2 both show a lower dielectric constant of 95 to 96%, and a lower dielectric loss tangent of 55 to 65%, as compared with the test piece of Comparative Example, as well as less number of free hydroxyl group in the test pieces, as compared with Comparative Example. In addition, there was little difference on measurement results of dielectric properties also, similarly as measurement results of glass transition temperature.

Accordingly, it is understood that, in Examples 1 and 2, although they contain a hydroxyl group protection-type Curing agent as a blending component, curing was progressed smoothly, and a cured product having low dielectric constant and low dielectric loss tangent is possible to provide.

### INDUSTRIAL APPLICABILITY

According to the present invention, there is provided an insulating material suitable for an interlayer insulating material using an epoxy resin composition having both excellent dielectric properties and practical characteristics.

According to an insulating material using a specific epoxy resin composition of the present invention, it becomes possible to provide an insulating material for a multilayer printed circuit board having both excellent dielectric properties and practical characteristics.

The epoxy resin composition and the cured product thereof which the present invention provides can be used suitably for an interlayer insulating material application for a multilayer printed circuit board for a high frequency signal where low transmission loss is required.

1. An insulating material obtained by using an epoxy resin composition comprising, as an epoxy resin curing agent, a polycondensation-type aryloxysilane compound contained in an amount of 50 to 100 wt %, having a skeleton shown by the following general formula (1) and having a hydroxyl group equivalent in a range of 1,000 to 8,000 g/eq, and an epoxy resin having an epoxy equivalent of 200 to 500, wherein a thermally cured product obtained by curing this epoxy resin composition at a temperature of 180° C. or lower, shows a dielectric constant and a dielectric loss tangent of 3.00 or smaller and 0.015 or smaller, respectively, at 1 GHz under normal temperature: 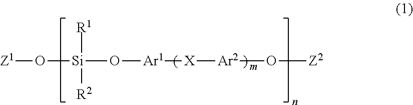
(wherein R¹ and R² represent hydrocarbon groups having carbon atoms of 1 to 12; Ar¹ and Ar² represent arylene groups having carbon atoms of 6 to 10, wherein a substitution group may be present; X represents a direct bonding, a divalent hydrocarbon group having carbon atoms of 1 to 6, O, S or SO₂; m represents an integer of 0 to 2; n represents an integer of 1 to 20; Z¹ represents a group shown by the following general formula (2); and Z² represents hydrogen or a group shown by the following general formula (3))
HO—Ar¹X—Ar²ₘ (2)
(wherein Ar¹, Ar² and X are the same as in formula (1)) 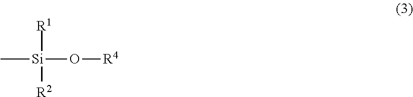
(wherein R¹ and R² are the same as in formula (1), and R⁴ represents an alkyl group having carbon atoms of 1 to 4).

2. The insulating material according to claim 1, wherein R¹ and R² of said epoxy resin curing agent are a methyl group or a phenyl group, Ar¹ and Ar² are a phenylene group or a naphthylene group.

3. An insulating material obtained by using an epoxy resin cured product, wherein a thermally cured product obtained by thermal curing of the epoxy resin composition according to claim 1 shows a dielectric constant of 3.00 or smaller and a dielectric loss tangent of 0.015 or smaller, at 1 GHz under normal temperature.

4. The insulating material according to claim 1, wherein said insulating material is an interlayer insulating material of a multilayer printed circuit board.

5. A multilayer printed circuit board prepared by using the interlayer insulating material according to claim 4.

6. The insulating material according to claim 2, wherein said insulating material is an interlayer insulating material of a multilayer printed circuit board.

7. A multilayer printed circuit board prepared by using the interlayer insulating material according to claim 6.

8. The insulating material according to claim 3, wherein said insulating material is an interlayer insulating material of a multilayer printed circuit board.

9. A multilayer printed circuit board prepared by using the interlayer insulating material according to claim 8.

10. An insulating material obtained by using an epoxy resin cured product, wherein a thermally cured product obtained by thermal curing of the epoxy resin composition according to claim 2 shows a dielectric constant of 3.00 or smaller and a dielectric loss tangent of 0.015 or smaller, at 1 GHz under normal temperature.

11. The insulating material according to claim 10, wherein said insulating material is an interlayer insulating material of a multilayer printed circuit board.

12. A multilayer printed circuit board prepared by using the interlayer insulating material according to claim 11.
